(19) United States
(12) Patent Application Publication
(10) Pub. No.: US 2020/0045813 A1
(43) Pub. Date: Feb. 6, 2020

(54) REINFORCING MEMBER FOR FLEXIBLE PRINTED WIRING BOARD, AND FLEXIBLE PRINTED WIRING BOARD PROVIDED WITH SAME

(71) Applicant: TATSUTA ELECTRIC WIRE & CABLE CO., LTD., Higashiosaka-shi (JP)

(72) Inventors: Hiroshi TAJIMA, Kizugawa-shi (JP); Masahiro WATANABE, Kizugawa-shi (JP)

(21) Appl. No.: 16/583,509

(22) Filed: Sep. 26, 2019

Related U.S. Application Data
(62) Division of application No. 15/507,431, filed on Feb. 28, 2017.

(30) Foreign Application Priority Data
Aug. 29, 2014 (JP) 2014-175278

(51) Int. Cl. H05K 1/02; H05K 1/18; H05K 1/09

(52) U.S. Cl. CPC H05K 1/0281; H05K 1/189; H05K 1/09; H05K 1/0218; H05K 3/321; H05K 2201/2009; H05K 2201/1028; H05K 2201/0715; H05K 1/0215

(57) ABSTRACT

A reinforcing member for a flexible printed wiring board allows a ground wiring pattern of the flexible printed wiring board to conduct with an external ground potential. The reinforcing member includes a metal base and a nickel layer formed on a surface of the metal base. The nickel layer includes phosphorus in a range from 5.0 percent by mass to 20.0 percent by mass, the rest of the nickel layer is nickel and inevitable impurities, and the nickel layer is 0.2 μm to 0.9 μm thick.

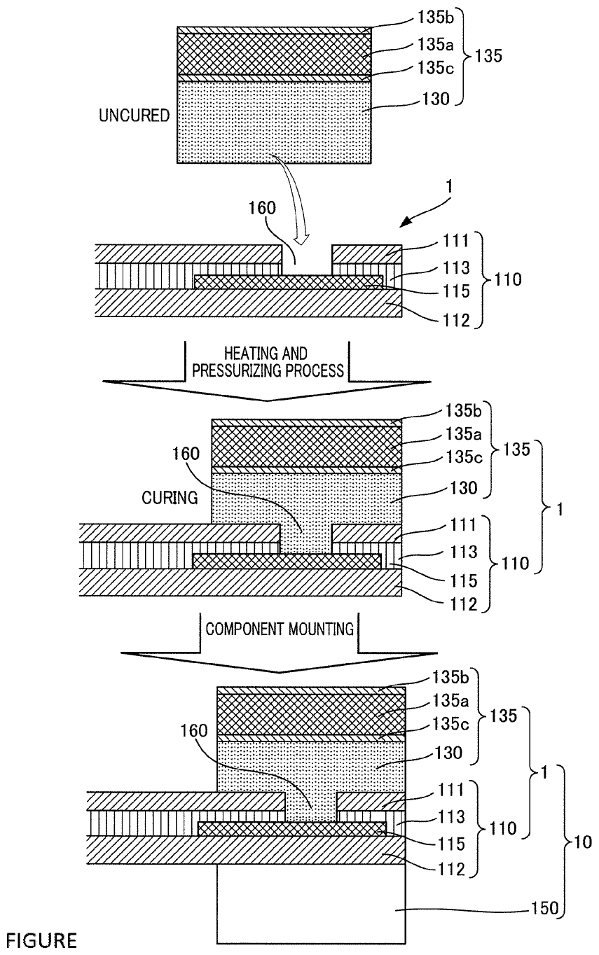

### CROSS-REFERENCE TO RELATED APPLICATIONS

This application is a division of U.S. application Ser. No. 15/507,431 filed Feb. 28, 2017, the priority benefit of which is claimed and the contents of which are incorporated herein by reference. That application, in turn, is the U.S. National Stage entry of PCT application PCT/JP2015/074722 filed internationally on Aug. 31, 2015, the priority benefit of which is claimed and the contents of which are incorporated herein by reference. The PCT application, in turn, is based on and claims priority to underlying Japanese application 2014-175278 filed Aug. 29, 2014, the priority benefit of which is claimed and the contents of which are incorporated herein by reference.

### TECHNICAL FIELD

The present invention relates to a reinforcing member for a flexible printed wiring board used in a mobile phone, a computer, or the like, and a flexible printed wiring board including the reinforcing member.

### BACKGROUND ART

A known flexible printed wiring board is structured such that, in order to prevent an electronic component from dropping off when the wiring board is warped, a reinforcing member is provided on a surface opposite to the surface on which the electronic component is provided, with the result that warpage of the mounting position of the electronic component is prevented by the reinforcing member. Patent Literature 1 and Patent Literature 2 propose structures in each of which a reinforcing member is formed of a metal reinforcing plate and a ground circuit of a flexible printed wiring board is connected to a housing in a conductive state via the metal reinforcing plate.

These structures, however, are disadvantageous in that, when the reinforcing member is used in high-temperature and high-humidity environments, a pealing value (i.e., the force required for peeling) of the reinforcing member is decreased with respect to a conductive adhesive, with the result that the electric resistance in the conductive state is increased. In this connection, Patent Literature 3 proposes to use a reinforcing member in which a nickel layer is formed on the surface of a stainless base, in order to stably keep the electric resistance to be low under environments with a wide range of temperatures and a wide range of humidity from room temperature and humidity to high temperature and humidity.

### CITATION LIST

### Patent Literatures

### [Patent Literature 1] Japanese Unexamined Patent Publication No. 2007-189091

### [Patent Literature 2] Japanese Unexamined Patent Publication No. 2009-218443

### [Patent Literature 3] Japanese Unexamined Patent Publication No. 2013-41869

### SUMMARY OF INVENTION

### Technical Problem

In these days, keeping pace with the reduction in thickness of apparatuses on which flexible printed wiring boards are mounted, reinforcing members used for the flexible printed wiring boards are required to be thin. Under this circumstance, the inventors of the subject application found a problem in connection with Patent Literature 3 that, when the surface layer of the reinforcing member was thinned to achieve reduction in thickness, the electric resistance increased in high-temperature and high-humidity environments. It is therefore desired to restrain the increase in the electric resistance under high-temperature and high-humidity environments in the same manner as in the known structures, even if the thickness of the surface layer of the reinforcing member is reduced.

The present invention was done to solve the problem above, and an object of the present invention is to provide a reinforcing member for a flexible printed wiring board, which has a thin layer but is able to restrain the increase in the electric resistance under high-temperature and high-humidity environments, and to provide a flexible printed wiring board including the reinforcing member.

### Solution to Problem

As a result of diligent efforts for solving the problem above, the inventors found that, when a nickel layer formed on a surface of a metal base included phosphorus, high heat resistance and high humidity resistance were achieved on the surface side of the metal base, on which the nickel layer including phosphorus (hereinafter, this layer may be simply referred to as a nickel layer) was formed. Based on this, the inventors have invented a reinforcing member for a flexible printed wiring board and a flexible printed wiring board, which are described below.

According to the first aspect of the invention, a reinforcing member for a flexible printed wiring board, which allows a ground wiring pattern of the flexible printed wiring board to conduct with an external ground potential, includes: a metal base; and a nickel layer formed on a surface of the metal base, the nickel layer including phosphorus in a range from 5 percent by mass to 20 percent by mass, the rest of the nickel layer being nickel and inevitable impurities, and the nickel layer being 0.2 μm to 0.9 μm thick.

According to this configuration, in the reinforcing member for the flexible printed wiring board, because the nickel layer including phosphorus in a range of 5 percent by mass to 20 percent by mass is formed on the surface of the metal base, the nickel layer functions as a protective layer for protecting the metal base from heat and humidity. Because the nickel layer prevents deterioration of the metal base due to heat and humidity, high heat resistance and high humidity resistance are achieved as compared to cases where the reinforcing member is formed solely of the metal base. In the reinforcing member above, it is therefore possible, by means of the nickel layer, to restrain the progress of deterioration which is increase in the electric resistance, even if the surface side of the metal base on which the nickel layer is formed is exposed to high-temperature and high-humidity environments. As a result, because increase in the electric resistance in high-temperature and high-humidity environments is restrained, the connection position of connecting the reinforcing member to the flexible printed wiring board is reinforced predominantly by the strength of the metal base, and at the same time, by the nickel layer, the ground effect which is achieved by causing the ground wiring pattern to conduct with an external ground potential is maintained in a high condition for a long time. Furthermore, the material cost is reduced and the yield in punching and cutting for separating a group of the reinforcing members into pieces is improved, while desired heat resistance and humidity resistance are achieved.

The metal base of the first aspect of the invention may be made of stainless steel, aluminum, or aluminum alloy.

According to the configuration above, the metal base is thinned while the strength of the reinforcing member above is maintained in a high condition.

The reinforcing member for the flexible printed wiring board according to the first aspect of the invention may include a conductive adhesive layer which is provided on the ground wiring pattern side of the metal base.

According to the configuration above, because of the inclusion of the conductive adhesive layer, the reinforcing member is easily connected to the ground wiring pattern of the flexible printed wiring board in a conductive state.

According to the second aspect of the invention, a flexible printed wiring board includes the reinforcing member of the first aspect of the invention.

According to the configuration above, even if the flexible printed wiring board is repeatedly warped, the part with which the reinforcing member of the first aspect of the invention is joined is unlikely to be warped. On this account, it is possible to prevent the occurrence of a problem such as drop off of an electronic component provided at the position corresponding to the above-described reinforcing member from the flexible printed wiring board. Furthermore, because of the inclusion of the above-described reinforcing member, the ground wiring pattern is allowed to conduct with the external ground potential via the above-described reinforcing member. The ground effect is therefore maintained in a high condition for a long time by the nickel layer.

### Advantageous Effects of Invention

Increase in an electric resistance is restrained under high-temperature and high-humidity environments, even if the thickness of a surface layer of a reinforcing member is reduced, and hence a ground effect is maintained in a high condition for a long time.

### BRIEF DESCRIPTION OF DRAWINGS

The FIGURE illustrates a process of manufacturing a flexible printed wiring board of an embodiment.

### DESCRIPTION OF EMBODIMENTS

The following will describe a preferred embodiment of the present invention with reference to figures.

### (Reinforcing Member for Flexible Printed Wiring Board)

As shown in the FIGURE, a reinforcing member 135 for a flexible printed wiring board (hereinafter, reinforcing member 135) of the present embodiment includes a metal base 135a and nickel layers 135b and 135c formed on the surfaces of the metal base 135a. The nickel layers 135b and 135c include phosphorus.

With this configuration, in the reinforcing member 135, because the surfaces of the metal base 135a are covered with the nickel layers 135b and 135c including phosphorus, the nickel layers 135b and 135c function as protective layers of the metal base 135a, and hence the metal base 135a is protected from heat and humidity. As a result, thanks to the nickel layers 135b and 135c, the reinforcing member 135 has high heat resistance and high humidity resistance as compared to cases when the reinforcing member 135 is formed solely of the metal base 135a. It is therefore possible to restrain the progress of deterioration which is increase in the electric resistance on account of degeneration of the metal base 135a, even if the surface sides of the metal base 135a on which the nickel layers 135b and 135c are formed are exposed to high-temperature and high-humidity environments.

The reinforcing member 135 configured as above is mounted on a flexible printed wiring board 1. The reinforcing member 135 is connected to a ground wiring pattern 115 of the flexible printed wiring board 1 in a conductive state. With this configuration, the reinforcing member 135 reinforces the connection position of connecting the reinforcing member 135 to the flexible printed wiring board 1 predominantly by the strength of the metal base 135a, and at the same time, by the nickel layers 135b and 135c, the reinforcing member 135 maintains the ground effect, which is achieved by causing the ground wiring pattern 115 to conduct with an external ground potential, in a high condition for a long time.

The above-described reinforcing member 135 is formed to be a thin plate and includes a connection surface (lower surface) connected to the ground wiring pattern 115, an open surface (upper surface) electrically connected with an external ground at the ground potential, and side surfaces sandwiched between the connection surface and the open surface. The metal base 135a of the reinforcing member 135 is positionally between the connection surface and the open surface. The nickel layers 135b and 135c are provided on the connection surface and the open surface, respectively. The reinforcing member 135 is provided to oppose the ground wiring pattern 115 of the flexible printed wiring board 1. One of the opposing surfaces (connection surface) is connected to the ground wiring pattern 115 in a conductive state, and the other one of the surfaces (open surface) is connected in a conductive state to an unillustrated external ground member which is at the ground potential.

The term “connected in a conductive state” encompasses not only a state in which connection is achieved by direct contact or abutting but also a state in which connection is indirectly achieved via a later-described conductive adhesive layer 130 or the like. The nickel layers 135b and 135c may be formed only on the open surface of the reinforcing member 135, or may be formed on the entire surfaces of the reinforcing member 135, which are constituted by the connection surface, the open surface, and the side surfaces.

(Reinforcing Member for Flexible Printed Wiring Board: Metal Base) The metal base 135a is made of stainless steel. The metal base 135a therefore makes it possible to reduce the thickness of the reinforcing member 135 while maintaining the strength of the reinforcing member 135 in a high condition. The metal base 135a is preferably made of stainless steel in consideration of corrosion resistance, strength, etc. The metal base 135a, however, is not limited to this and may be made of another type of metal. For example, the metal base 135a may be made of aluminum, nickel, copper, silver, tin, gold, palladium, chromium, titanium, zinc, or alloy of two or more of these materials.

The minimum thickness of the metal base 135a is preferably 0.05 mm, and more preferably 0.1 mm. The maximum thickness of the metal base 135a is preferably 1.0 mm, and more preferably 0.3 mm. The thickness above should not be particularly limited and may be suitably set.

### (Reinforcing Member for Flexible Printed Wiring Board: Nickel Layer)

The nickel layers 135b and 135c include 5 percent by mass to 20 percent by mass of phosphorus, and the rest is nickel and inevitable impurities. The minimum content (percentage by mass) of phosphorus in the nickel layers 135b and 135c is preferably 5 percent by mass, and more preferably 10 percent by mass. The maximum content (percentage by mass) of phosphorus in the nickel layers 135b and 135c is preferably 20 percent by mass, and more preferably 15 percent by mass.

When phosphorus is included in the range above, the nickel layers 135b and 135c exhibit high humidity resistance as compared to cases where no phosphorus is included. This makes it possible to hamper the speed of generation of a passive film on the reinforcing member 135 due to external environments such as temperature and humidity, aged deterioration, etc., after the reinforcing member 135 is pasted onto the flexible printed wiring board 1. As such, the nickel layers 135b and 135c prevent the electric resistance of the reinforcing member 135 from becoming high on account of a passive film, and hence the ground effect is maintained for a long time. In other words, the reinforcing member 135 for the flexible printed wiring board improves the shielding performance and durability of the flexible printed wiring board 1, which are required under environments with a wide temperature range and a wide humidity range from room temperatures and humidity to high temperatures and humidity.

The nickel layers 135b and 135c may be formed on the entire surfaces of the metal base 135a, or may be formed on parts thereof. This because, as the nickel layers 135b and 135c cover the surfaces of the metal base 135a, the size of an area exposed to the outside air on the metal base 135a is decreased, and hence the size of an area where a passive film is formed on the metal base 135a is decreased. For example, each of the nickel layers 135b and 135c may be a group of lines, a group of dots, or a mixture of lines and dots. The group of lines is, for example, a stripe pattern or a matrix. The group of dots is, for example, a polka dot pattern.

The nickel layers 135b and 135c may be formed by electroless plating or electrolytic plating. Preferably, the layers are formed by electrolytic plating on account of good productivity. For example, the nickel layers 135b and 135c are formed by dipping a large-sized metal base 135a into a plating bath, and then the metal base 135a is cut in longitudinal and lateral directions into pieces each having predetermined dimensions, together with the nickel layers 135b and 135c. As a result, plural reinforcing members 135 are obtained. Instead of the plating, the nickel layers 135b and 135c may be formed by vapor deposition or the like.

The thickness of each of the nickel layers 135b and 135c is set at 0.2 μm to 0.9 μm. With this setting, the material cost of nickel is reduced and the yield in punching and cutting for separating the group of the reinforcing members 135 into pieces is improved, while desired heat resistance and humidity resistance are achieved. The minimum thickness of each of the nickel layers 135b and 135c is preferably 0.2 μm and more preferably 0.3 μm, in order to obtain sufficient corrosion resistance, heat resistance, and humidity resistance of the reinforcing member 135. The maximum thickness of each of the nickel layers 135b and 135c is preferably 0.9 μm and more preferably 0.6 μm in consideration of costs.

### (Reinforcing Member for Flexible Printed Wiring Board: Conductive Adhesive Layer)

The reinforcing member 135 configured as above may include a conductive adhesive layer 130. The conductive adhesive layer 130 is provided on the lower surface side of the metal base 135a. To be more specific, the conductive adhesive layer 130 is laminated on the nickel layer 135c which is on the lower surface side of the metal base 135a. Because of the presence of the conductive adhesive layer 130 in the reinforcing member 135, it is possible to omit the step of attaching the conductive adhesive layer 130 to the reinforcing member 135 when the reinforcing member 135 is attached to a flexible printed wiring board main body 110. It is therefore possible to easily connect the reinforcing member 135 to the ground wiring pattern 115 of the flexible printed wiring board 1 in a conductive state.

The conductive adhesive layer 130 is formed of an isotropic conductive adhesive or an anisotropic conductive adhesive. The electrical property of the isotropic conductive adhesive is similar to that of known solder. For this reason, when the conductive adhesive layer 130 is formed of an isotropic conductive adhesive, electric conduction is achieved in all three dimensional directions consisting of thickness directions, width directions, and longitudinal directions. In the meanwhile, when the conductive adhesive layer 130 is formed of an anisotropic conductive adhesive, electric conduction is achieved only in two dimensional directions consisting of thickness directions. The conductive adhesive layer 130 may be formed of a conductive adhesive in which conductive particles mainly made of a soft magnetic material are mixed with an adhesive.

Examples of the adhesive in the conductive adhesive layer 130 include acryl-based resin, epoxy-based resin, silicon-based resin, thermoplastic elastomer-based resin, rubber-based resin, polyester-based resin, and urethane-based resin. The adhesive may be made of one of these resins or a mixture of two or more of the resins. The adhesive may further include a tackifier. Examples of the tackifier include fatty acid hydrocarbon resin, C5/C9 mixed resin, rosin, rosin derivative, terpene resin, aromatic hydrocarbon resin, and thermal reactive resin.

While in the present embodiment the conductive adhesive layer 130 is laminated on the nickel layer 135c, the disclosure is not limited to this. That is to say, the conductive adhesive layer 130 may be directly laminated on the lower surface of the metal base 135a, as the nickel layer 135c is excluded. The reinforcing member 135 includes or does not include the conductive adhesive layer 130 according to need. To put it differently, the reinforcing member 135 may include the metal base 135a and the nickel layers 135b and 135c, or may include the metal base 135a, the nickel layers 135b and 135c, and the conductive adhesive layer 130.

### (Flexible Printed Wiring Board)

The reinforcing member 135 configured as above is mounted on the flexible printed wiring board 1 which is flexible and bendable. In this connection, the flexible printed wiring board 1 may be used as a rigid flexible printed wiring board integrated with a rigid substrate.

The flexible printed wiring board 1 includes the flexible printed wiring board main body 110 and the reinforcing member 135 connected to one surface of the flexible printed wiring board main body 110. The flexible printed wiring board main body 110 includes the ground wiring pattern 115, and the ground wiring pattern 115 is connected to the conductive adhesive layer 130 of the reinforcing member 135. An electronic component 150 is mounted on a mounting position of the flexible printed wiring board 1, which position is on the side opposite to the connection position where the reinforcing member 135 is connected and which corresponds to the reinforcing member 135. With this configuration, a flexible printed board 10 is formed.

The flexible printed board 10 reinforces the mounting position of the electronic component 150 as the reinforcing member 135 reinforces the connection position where the reinforcing member 135 is connected to the flexible printed wiring board main body 110. Furthermore, in the flexible printed board 10, the ground wiring pattern 115 is grounded to an external ground member (not illustrated) at the ground potential via the reinforcing member 135, as the reinforcing member 135 is connected to the external ground member. The external ground member is, for example, a housing of an electronic apparatus (not illustrated). With this configuration, the ground wiring pattern 115 conducts with the external ground member via the reinforcing member 135 when the flexible printed board 10 is embedded in the electronic apparatus, with the result that a good ground effect is achieved.

### (Flexible Printed Wiring Board: Flexible Printed Wiring Board Main Body)

The flexible printed wiring board main body 110 includes a base member 112 on which plural wiring patterns such as an unillustrated signal wiring pattern and the ground wiring pattern 115 are formed, an adhesive layer 113 formed on the base member 112, and an insulating film 111 adhered to the adhesive layer 113.

The unillustrated signal wiring pattern and the ground wiring pattern 115 are formed on the upper surface of the base member 112. These wiring patterns are formed by etching a conductive material. Among the wiring patterns, the ground wiring pattern 115 indicates a pattern which is kept at the ground potential.

The adhesive layer 113 is an adhesive provided between the wiring patterns such as the signal wiring pattern and the ground wiring pattern 115 and the insulating film 111. This adhesive layer 113 maintains insulation and allows the insulating film 111 to be adhered to the base member 112. The thickness of the adhesive layer 113 falls within the range of 10 μm to 40 μm. The thickness, however, is not particularly limited and may be suitably set.

The base member 112 and the insulating film 111 are both made of engineering plastics. Examples of the engineering plastics include resins such as polyethylene terephthalate, polypropylene, cross-linked polyethylene, polyester, polybenzimidazole, polyimide, polyimidoamide, polyetherimide, and polyphenylene sulfide. When heat resistance is not required so much, a polyester film is preferred for its inexpensiveness. When fire retardance is required, a polyphenylene sulfide film is preferred. When heat resistance is further required, a polyimide film, a polyamide film, or a glass epoxy film is preferred. The thickness of the base member 112 falls within the range of 10 μm to 40 μm and the thickness of the insulating film 111 falls within the range of 10 μm to 30 μm, but they are not particularly limited and may be suitably set.

Through the insulating film 111 and the adhesive layer 113 described above, a hole part 160 is formed by using a mold or the like. The hole part 160 allows a partial area of a wiring pattern selected from the signal wiring patterns and the ground wiring pattern to be exposed. In the present embodiment, the hole part 160 is formed in the direction in which the insulating film 111 and the adhesive layer 113 are laminated, so that a partial area of the ground wiring pattern 115 is exposed to the outside. The hole diameter of the hole part 160 is suitably determined so that a neighboring wiring pattern is not exposed.

In the flexible printed wiring board main body 110, a film for shielding electromagnetic waves may be provided on the upper surface of the insulating film 111. This film includes a conductive member, a conductive layer adhered to and in contact with the conductive member, and an insulating layer provided on the conductive layer.

### (Method of Attaching Reinforcing Member to Flexible Printed Wiring Board Main Body)

To begin with, the reinforcing member 135 in which the nickel layers 135b and 135c are formed on the upper surface and the lower surface of the metal base 135a is prepared. In other words, the nickel layers 135b and 135c are formed by dipping the large-sized metal base 135a into the plating bath. Then the conductive adhesive layer 130 is pasted onto or coated on the lower-side surface of the large-sized metal base 135a. The large-sized reinforcing member 135 is then cut in longitudinal and lateral directions into pieces each having predetermined dimensions, with the result that, plural reinforcing members 135 are obtained.

Subsequently, the reinforcing member 135 is placed on the flexible printed wiring board main body 110 so that the conductive adhesive layer 130 opposes the hole part 160. Then, at a first pressure (0.5 MPa) and for a first time (e.g., five seconds), the reinforcing member 135 and the flexible printed wiring board main body 110 are pressed from above and from below by two heating plates which are at a first temperature (e.g., 120 degrees centigrade). As a result of this, the reinforcing member 135 is tentatively attached to the flexible printed wiring board main body 110.

Subsequently, the two heating plates are heated to a second temperature (170 degrees centigrade) which is higher than the temperature at the time of the tentative attachment. Then, at a second pressure (3 MPa) and for a second time (e.g., 30 minutes), the reinforcing member 135 and the flexible printed wiring board main body 110 are pressed from above and from below by the heating plates which are at the second temperature. In this way, the reinforcing member 135 is fixedly attached to the flexible printed wiring board main body 110, at the same time the hole part 160 is filled with the conductive adhesive layer 130.

As described above, because thermal treatment is carried out when the reinforcing member 135 is attached to the flexible printed wiring board main body 110, a passive film is formed on the reinforcing member 135 and the electric resistance is increased, if the corrosion resistance of the reinforcing member 135 is low. In this regard, in the present embodiment, the nickel layers 135b and 135c are formed on the surfaces of the metal base 135a of the reinforcing member 135. It is therefore possible to prevent the formation of a passive film on account of thermal treatment in the process of manufacturing the flexible printed wiring board 1.

The detailed description of the present invention provided hereinabove mainly focused on characteristics thereof for the purpose of easier understanding; however, the scope of the present invention shall be construed as broadly as possible, encompassing various forms of other possible embodiments. Further, the terms and phraseology used in the present specification are adopted solely to provide specific illustration of the present invention, and in no case should the scope of the present invention be limited by such terms and phraseology. Further, it will be obvious for those skilled in the art that the other structures, systems, methods or the like are possible, within the spirit of the present invention described in the present specification. Accordingly, it should be considered that claims cover equivalent structures, too, without departing from the technical idea of the present invention. In addition, it is desirable to sufficiently refer to already-disclosed documents and the like, in order to fully understand the objects and effects of the present invention.

For example, the flexible printed wiring board 1 of the present embodiment may be arranged such that a film is provided on the insulating film 111. This film includes a conductive member provided on the insulating film 111, a conductive layer adhered to and in contact with the conductive member, and an insulating layer provided on the conductive layer. Because of the inclusion of the conductive layer, the film has a function of shielding electromagnetic waves.

### EXAMPLES

In regard to a reinforcing member in which a nickel layer including phosphorus was formed on a surface of a metal base by using a nickel sulfate bath, electric resistance and humidity resistance were measured. The thickness of the nickel layer was 0.1 μm, 0.2 μm, 0.3 μm, 0.5 μm, 0.6 μm, 0.8 μm, 0.9 μm, or 1.0 μm. The measurements were done by changing the phosphorus content to 2.5 percent by mass, 5.0 percent by mass, 7.0 percent by mass, 10.0 percent by mass, 12.5 percent by mass, 15.0 percent by mass, 18.0 percent by mass, 20.0 percent by mass, and 22.5 percent by mass, for each thickness. The results of the measurements were Comparative Example 1 and Examples 1 to 7. The phosphorus content was measured by using a X-ray fluorescence coating thickness gauge (SFT-3200 made by Hitachi Science Corporation), under the following conditions: the X-ray tube was a tungsten target, the tube voltage was 45 kV, the tube current was 1000 μA, the collimator diameter was 0.1 mmφ, and the measurement time was 20 seconds. Furthermore, a standard curve was prepared by using nickel foils (0.49 μm thick and 0.99 μm thick) and NiP alloy with 10% phosphorus as standard foils.

In regard to a reinforcing member in which a nickel layer (phosphorus content is equal to or lower than the detection limit) formed on the surface of a metal base by electrolytic plating by using a nickel sulfamate bath, electric resistance and humidity resistance were measured as Comparative Examples. The thickness of the nickel layer in the reinforcing member was 0.6 μm, 0.8 μm, 0.9 μm, 1.0 μm, or 2.0 μm, as Comparative Examples 2 to 6.

The metal bases of the reinforcing members were all SUS304H each of which was a stainless steel pipe in accordance with JISG3459. In both of the measurement of the electric resistance and the test of the humidity resistance, each of the reinforcing members was left for 1000 hours in an environment of 85 degrees centigrade in temperature and 85% in humidity.

For the measurement of the electric resistance, a four-terminal resistance measuring apparatus was used. In the measurement, an electric resistance equal to or lower than 0.2Ω was evaluated as Good, an electric resistance higher than 0.2Ω and equal to or lower than 3.0Ω was evaluated as Average, and an electric resistance higher than 0.3Ω was evaluated as Poor.

The humidity resistance was measured in such a way that, after the reinforcing member was subjected to a nitrate aeration test defined in the attached document 1 of JIS-H8620, the surface (nickel layer) of the reinforcing member was observed. Overall discoloration of the surface was ignored, and a case where a few spots with a color (e.g., patina color, black, blackish color, brown, or dark brown) different from the overall color of the discolored surface were observed was evaluated as Good, a case where the degree of formation of the spots was between Good and Poor was evaluated as Average, and a case where the formation of the spots was significant in number was evaluated as Poor.

The nitrate aeration test was performed in the following steps. To begin with, dirt on the surface of the reinforcing member was removed by a solvent such as ethanol, benzine, or gasoline, and the surface was dried. Subsequently, 69 vol % of nitrate was put in a bottom portion of a desiccator, the dried reinforcing member was placed on a porcelain plate, and a lid is put thereon. After the reinforcing member was left for an hour at a room temperature of about 23 degrees centigrade, the reinforcing member was taken out, calmly washed by water, and dried. Then the surface layer (nickel layer) of the reinforcing member was observed.

In addition to the above, comprehensive evaluations were carried out as follows: a case where the evaluation of the electric resistance and the evaluation of the humidity resistance were both Good was evaluated as Excellent, a case where one of the evaluation of the electric resistance and the evaluation of the humidity resistance was Good and the other one was Average was evaluated as Good, a case where both of the evaluation of the electric resistance and the evaluation of the humidity resistance were Average was evaluated as Average, and a case where at least one of the evaluation of the electric resistance and the evaluation of the humidity resistance was Poor was evaluated as Poor.

The evaluation results of the reinforcing members in each of which the nickel layer including phosphorus was formed are shown in Table 1. Furthermore, as Comparative Examples, the evaluation results of the reinforcing members in each of which the nickel layer was formed on the surface of the metal base by electrolytic plating by using a nickel sulfamate bath are shown in Table 2.

TABLE 1

| | THICKNESS | | | | | |
|---|---|---|---|---|---|---|
| | OF PLATING | | PHOSPHORUS CONTENT (%) | | | |
| | (μm) | TESTS AND EVALUATIONS | 2.5 | 5.0 | 7.0 | 10.0 |
| COMPARATIVE | 0.1 | ELECTRIC RESISTANCE | POOR | POOR | POOR | POOR |
| EXAMPLE 1 | | HUMIDITY RESISTANCE | POOR | POOR | POOR | POOR |
| | | COMPREHENSIVE RESULT | POOR | POOR | POOR | POOR |
| EXAMPLE 1 | 0.2 | ELECTRIC RESISTANCE | AVERAGE | AVERAGE | AVERAGE | AVERAGE |
| | | HUMIDITY RESISTANCE | AVERAGE | AVERAGE | AVERAGE | AVERAGE |
| | | COMPREHENSIVE RESULT | AVERAGE | AVERAGE | AVERAGE | AVERAGE |
| EXAMPLE 2 | 0.3 | ELECTRIC RESISTANCE | GOOD | GOOD | GOOD | GOOD |
| | | HUMIDITY RESISTANCE | POOR | AVERAGE | AVERAGE | GOOD |
| | | COMPREHENSIVE RESULT | POOR | GOOD | GOOD | EXCELLENT |
| EXAMPLE 3 | 0.5 | ELECTRIC RESISTANCE | GOOD | GOOD | GOOD | GOOD |
| | | HUMIDITY RESISTANCE | POOR | AVERAGE | AVERAGE | GOOD |
| | | COMPREHENSIVE RESULT | POOR | GOOD | GOOD | EXCELLENT |
| EXAMPLE 4 | 0.6 | ELECTRIC RESISTANCE | GOOD | GOOD | GOOD | GOOD |
| | | HUMIDITY RESISTANCE | POOR | AVERAGE | AVERAGE | GOOD |
| | | COMPREHENSIVE RESULT | POOR | GOOD | GOOD | EXCELLENT |
| EXAMPLE 5 | 0.8 | ELECTRIC RESISTANCE | GOOD | GOOD | GOOD | GOOD |
| | | HUMIDITY RESISTANCE | POOR | AVERAGE | AVERAGE | AVERAGE |
| | | COMPREHENSIVE RESULT | POOR | GOOD | GOOD | GOOD |
| EXAMPLE 6 | 0.9 | ELECTRIC RESISTANCE | GOOD | GOOD | GOOD | GOOD |
| | | HUMIDITY RESISTANCE | POOR | AVERAGE | AVERAGE | AVERAGE |
| | | COMPREHENSIVE RESULT | POOR | GOOD | GOOD | GOOD |
| EXAMPLE 7 | 1.0 | ELECTRIC RESISTANCE | GOOD | GOOD | GOOD | GOOD |
| | | HUMIDITY RESISTANCE | POOR | AVERAGE | AVERAGE | AVERAGE |
| | | COMPREHENSIVE RESULT | POOR | GOOD | GOOD | GOOD |

| | PHOSPHORUS CONTENT (%) | | | | |
|---|---|---|---|---|---|
| | 12.5 | 15.0 | 18.0 | 20.0 | 22.5 |
| COMPARATIVE | POOR | POOR | POOR | POOR | POOR |
| EXAMPLE 1 | POOR | POOR | POOR | POOR | POOR |
| | POOR | POOR | POOR | POOR | POOR |
| EXAMPLE 1 | AVERAGE | AVERAGE | AVERAGE | AVERAGE | AVERAGE |
| | AVERAGE | AVERAGE | AVERAGE | AVERAGE | AVERAGE |
| | AVERAGE | AVERAGE | AVERAGE | AVERAGE | AVERAGE |
| EXAMPLE 2 | GOOD | GOOD | AVERAGE | AVERAGE | POOR |
| | GOOD | GOOD | GOOD | GOOD | GOOD |
| | EXCELLENT | EXCELLENT | GOOD | GOOD | POOR |
| EXAMPLE 3 | GOOD | GOOD | AVERAGE | AVERAGE | POOR |
| | GOOD | GOOD | GOOD | GOOD | GOOD |
| | EXCELLENT | EXCELLENT | GOOD | GOOD | POOR |
| EXAMPLE 4 | GOOD | GOOD | AVERAGE | AVERAGE | POOR |
| | GOOD | GOOD | GOOD | GOOD | GOOD |
| | EXCELLENT | EXCELLENT | GOOD | GOOD | POOR |
| EXAMPLE 5 | GOOD | GOOD | AVERAGE | AVERAGE | POOR |
| | AVERAGE | AVERAGE | GOOD | GOOD | GOOD |
| | GOOD | GOOD | GOOD | GOOD | POOR |
| EXAMPLE 6 | AVERAGE | AVERAGE | AVERAGE | AVERAGE | POOR |
| | GOOD | GOOD | GOOD | GOOD | GOOD |
| | GOOD | GOOD | GOOD | GOOD | POOR |
| EXAMPLE 7 | AVERAGE | AVERAGE | AVERAGE | AVERAGE | POOR |
| | GOOD | GOOD | GOOD | GOOD | GOOD |
| | GOOD | GOOD | GOOD | GOOD | POOR |

TABLE 2

| | THICK- | | |
|---|---|---|---|
| COMPAR- | NESS OF | | |
| ATIVE | PLATING | | |
| EXAMPLE | (μm) | TESTS AND EVALUATIONS | |
| 2 | 0.6 | ELECTRIC RESISTANCE | AVERAGE |
| | | HUMIDITY RESISTANCE | POOR |
| | | COMPREHENSIVE RESULT | POOR |
| 3 | 0.8 | ELECTRIC RESISTANCE | AVERAGE |
| | | HUMIDITY RESISTANCE | POOR |
| | | COMPREHENSIVE RESULT | POOR |
| 4 | 0.9 | ELECTRIC RESISTANCE | AVERAGE |
| | | HUMIDITY RESISTANCE | AVERAGE |
| | | COMPREHENSIVE RESULT | AVERAGE |
| 5 | 1.0 | ELECTRIC RESISTANCE | GOOD |
| | | HUMIDITY RESISTANCE | AVERAGE |
| | | COMPREHENSIVE RESULT | GOOD |
| 6 | 2.0 | ELECTRIC RESISTANCE | GOOD |
| | | HUMIDITY RESISTANCE | GOOD |
| | | COMPREHENSIVE RESULT | GOOD |

According to the evaluation results above, in the reinforcing members of Comparative Examples 2 to 6, good comprehensive results were achieved only when the thickness was 1.0 μm or more. In the meanwhile, in the reinforcing members of Examples 1 to 7 in each of which the nickel layer including phosphorus was formed, comprehensive results were good even when the thickness of the plating fell in the range of 0.2 to 0.9 μm. In addition to this, particularly good comprehensive results were achieved when the thickness of the plating fell in the range of 0.3 to 0.6 μm and the phosphorus content fell in the range of 10.0 to 15.0%. These results are detailed as below.

### Example 1

When the thickness of the plating was 0.2 μm, the electric resistance, humidity resistance, and comprehensive results were Average when the phosphorus content fell within the range of 2.5 to 22.5%.

### Examples 2, 3, and 4

When the thickness of the plating was 0.3 μm, 0.5 μm, or 0.6 μm, the electric resistance was Good when the phosphorus content fell within the range of 2.5% to 15.0%, the electric resistance was Average when the phosphorus content fell within the range of 18.0% to 20.0%, and the electric resistance was Poor when the phosphorus content was 22.5%.

In addition to the above, the humidity resistance when the phosphorus content was 2.5% was Poor, the humidity resistance when the phosphorus content fell within the range of 5.0% to 7.0% was Average, and the humidity resistance when the phosphorus content fell within the range of 10.0% to 22.5% was Good.

Consequently, comprehensive results were Poor when the phosphorus content fell within the range of 2.5% to 22.5%, comprehensive results were Good when the phosphorus content fell within the range of 5.0% to 7.0% or the range of 18.0% to 20.0%, and comprehensive results were Excellent when the phosphorus content fell within the range of 10.0% to 15.0%.

### Example 5

When the thickness of the plating was 0.8 μm, the electric resistance was Good when the phosphorus content fell within the range of 2.5% to 15.0%, the electric resistance was Average when the phosphorus content fell within the range of 18.0% to 20.0%, and the electric resistance was Poor when the phosphorus content was 22.5%.

In addition to the above, the humidity resistance when the phosphorus content was 2.5% was Poor, the humidity resistance when the phosphorus content fell within the range of 5.0% to 15.0% was Average, and the humidity resistance when the phosphorus content fell within the range of 18.0% to 22.5% was Good.

Consequently, comprehensive results were Poor when the phosphorus content was 2.5% or lower, comprehensive results were Good when the phosphorus content fell within the range of 5.0% to 20.0%, and comprehensive results were Excellent when the phosphorus content fell was 22.5% or higher.

### Examples 6 and 7

When the thickness of the plating was 0.9 μm or 1.0 μm, the electric resistance was Good when the phosphorus content fell within the range of 2.5% to 10.0%, the electric resistance was Average when the phosphorus content fell within the range of 12.5% to 20.0%, and the electric resistance was Poor when the phosphorus content was 22.5%.

In addition to the above, the humidity resistance when the phosphorus content was 2.5% was Poor, the humidity resistance when the phosphorus content fell within the range of 5.0% to 10.0% was Average, and the humidity resistance when the phosphorus content fell within the range of 12.5% to 22.5% was Good.

Consequently, comprehensive results were Poor when the phosphorus content was 2.5% or lower or when the phosphorus content was 22.5% or higher, and comprehensive results were Good when the phosphorus content fell within the range of 5.0% to 20.0%.

The results of Examples 1 to 7 indicate that, in order to obtain good electric resistance and humidity resistance, the thickness of the plating preferably falls within the range of 0.2 μm to 1.0 μm and the phosphorus content preferably falls within the range of 5.0% to 20.0%. More preferably, the thickness of the plating falls within the range of 0.3 μm to 0.6 μm and the phosphorus content falls within the range of 10.0 to 15.0%.

### REFERENCE SIGNS LIST

1 flexible printed wiring board
111 insulating film
112 base member
113 adhesive layer
115 ground wiring pattern
130 conductive adhesive layer
135 reinforcing member
135a metal base
135b and 135c nickel layers
150 electronic component
160 hole part

We claim:

1. A flexible printed wiring board, comprising:
a substrate;
a ground wiring pattern formed on the substrate; and
a reinforcing member that is electrically connected with the ground wiring pattern and which allows the ground wiring pattern to be electrically connected with an external ground potential, the reinforcing member comprising
a metal base including a connection surface that is electrically connected to the ground wiring pattern and an open surface to be connected to the external ground potential;
a nickel layer formed on the connection surface of the metal base; and
a conductive adhesive layer formed on the nickel layer, the ground wiring pattern being electrically connected to the reinforcing member via the conductive adhesive layer;
wherein the nickel layer includes phosphorus in a range from 5 percent by mass to 20 percent by mass, the rest of the nickel layer being nickel and inevitable impurities, and
the nickel layer is 0.2 μm to 0.9 μm thick.

2. The flexible printed wiring board of claim 1, wherein the metal base is made of stainless steel, aluminum, or aluminum alloy.
